(19) United States
(12) Patent Application Publication
(10) Pub. No.: US 2012/0286349 A1
(43) Pub. Date: Nov. 15, 2012

(54) Non-Volatile Memory Device With Additional Conductive Storage Layer

(75) Inventor: Shyue Seng Tan, Singapore (SG)

(73) Assignee: GLOBALFOUNDRIES SINGAPORE PTE LTD, Singapore (SG)

(21) Appl. No.: 13/107,160

(22) Filed: May 13, 2011

(51) Int. Cl. H01L 29/788

(52) U.S. Cl. 257/324; 257/E29.3

(57) ABSTRACT

In one example, the memory device includes a gate insulation layer, a first conductive storage layer positioned above the gate insulation layer and a first non-conductive charge storage layer positioned above the first conductive storage layer. The device further includes a blocking insulation layer positioned above the first non-conductive charge storage layer and a gate electrode positioned above said blocking insulation layer.

### BACKGROUND OF THE INVENTION

1. Field of the Invention

Generally, the present disclosure generally relates to the manufacturing of sophisticated semiconductor devices, and, more specifically, to novel non-volatile memory devices with an additional conductive storage layer.

2. Description of the Related Art

Non-volatile memory devices are in widespread use in many modern integrated circuit devices and in many consumer products. In general, memory devices are the means by which electrical information is stored. FIG. 1A depicts one illustrative example of a prior art memory device 100. In general, the memory device 100 includes a gate insulation layer 20 (sometimes referred to as a “tunnel oxide”), a charge storage layer 22, a blocking insulation layer 24, a gate electrode 26, spacers 28, and illustrative source/drain regions 30. The illustrative memory device 100 is formed in and above the active layer 10C of the semiconducting substrate 10. An illustrative isolation structure 12, e.g., a shallow trench isolation structure, that is formed in the substrate 10 to electrically isolate the memory device 100 from other adjacent devices is also depicted. In one illustrative embodiment, the semiconducting substrate 10 a silicon-on-insulator (SOI) substrate comprised of bulk silicon 10A, a buried insulation layer 10B (commonly referred to as a “BOX” layer) and an active layer 10C, which may also be a silicon material. The various structures depicted in FIG. 1A may be made from a variety of material. In one typical configuration that is commonly employed the gate insulation layer 20 and the blocking insulation layer 24 are made of silicon dioxide, the charge storage layer 22 is made of silicon nitride (or a silicon rich nitride), and the gate electrode 26 is made of polysilicon. This is sometimes referred to as an “ONO” type memory device because of the materials employed (Oxide-Nitride-Oxide), a charge trapping or a SONOS (Silicon-Oxide-Nitride-Oxide-Silicon) type memory device as electrons are trapped in the non-conductive charge storage layer. In another common configuration, the gate insulation layer 20 and the blocking insulation layer 24 are made of silicon dioxide, while the charge storage layer 22 and the gate electrode 26 are made of polysilicon. This is sometimes referred to as a “floating gate” type memory device.

Millions of such memory devices 100 are typically included in even very basic electronic consumer products. Irrespective of the type of memory device, there is a constant drive in the industry to increase the performance and durability of such memory devices. In typical operations, an electrical charge is stored on the charge storage layer 22 to represent a digital “1” while the absence of such an electrical charge on the charge storage layer 22 indicates a digital “0”. Special read/write circuitry is used to access the memory device 100 to store information on such a memory device and to determine whether or not a charge is present on the charge storage layer 22 of the memory device 100. These program/erase cycles (“P/E cycles”) typically occur millions of times for a single memory device 100 over its effective lifetime.

Data retention is an important characteristic of all memory devices. Typically, floating gate memory devices exhibit better data retention than do the charge trapping type memory devices. This occurs because of the reduced conduction band offset (“ΔEc”) of the silicon nitride charge storage layer 22 as compared to the conductive charge storage layer (the “floating gate”) that is employed in floating gate type devices. For example, the conduction band offset (“ΔEc”) to the gate insulation layer is about 1.1 eV for a SONOS type device whereas it is about 3.4 eV for a floating gate type device. It is also well known that the reduced trapping energy of the silicon nitride charge storage layer 22 in a SONOS type device allows stored charges to escape at high temperatures. In short, data retention is an area for improvement in both the SONOS and the floating gate type memory devices.

Efforts have been made in the past to improve the data retention capability of SONOS type memory devices. FIG. 1B depicts an illustrative example of a memory device 101 that has been suggested to improve data retention. An illustrative energy band diagram for the memory device 101 is depicted in FIG. 1E. In general, in the device 101, an “ONO” type layer structure is positioned below the charge storage layer 22. More specifically, the device includes a first layer of silicon dioxide 20A, a layer of silicon nitride 23 positioned above the first layer of silicon dioxide 20A, and a second layer of silicon dioxide 20B positioned above the layer of silicon nitride 23. The additional layer of silicon nitride 23 is believed to assist in preventing stored charges from leaking away from the device 101. An illustrative example of such a device is described in, for example, H. T. Lue, et al., IEDM 2005, pg. 547; S. K Sung et al., IEEE Silicon Nanoelec. Workshop 2002, pg. 83.

FIG. 1C depicts another illustrative example of a memory device 102 that has been suggested to improve data retention. An illustrative energy band diagram for the memory device 102 is depicted in FIG. 1F. In general, in the device 102, a layer of silicon nano-crystals 25 is effectively positioned between two layers of silicon nitride 22A, 22B. It is suggested that that a memory device 102 that includes this layer of silicon nano-crystals 25 exhibits improve data retention and improved erase/programming speeds. An illustrative example of such a device is described in, for example, T-Y. Chiang, et al., IEEE T-ED vol 57, pg. 1895, 2010; IEEE EDL vol 29, pg 1148, 2008. S. Choi, et al., IEDM 2005.

FIG. 1D depicts yet another illustrative example of a memory device 103 that has been suggested to improve data retention. An illustrative energy band diagram for the memory device 103 is depicted in FIG. 1G. In general, in the device 103, a layer of silicon 27 is effectively positioned between two relatively thin layers (e.g., 1-3 nm) of silicon dioxide 20A, 20B. It is suggested that that a memory device 102 that includes this layer of silicon also exhibits improve data retention. An illustrative example of such a device is described in, for example, Ohba et al., IEDM 2008, pg. 839.

Unfortunately prior art SONOS type memory devices, such as those described above, still need improvement in data retention capabilities to meet the demands of current and future applications. The present disclosure is directed to various methods and resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the inven-tion or to delineate the scope of the invention. Its sole purpose is to present some concepts in a simplified form as a prelude to the more detailed description that is discussed later.

Generally, the present disclosure is directed to the manufacturing of sophisticated semiconductor devices, and, more specifically, to non-volatile memory devices that include an additional conductive storage layer. In one example, the memory device includes In one example, the memory device includes a gate insulation layer, a first conductive storage layer positioned above the gate insulation layer and a first non-conductive charge storage layer positioned above the first conductive storage layer. The device further includes a blocking insulation layer positioned above the first non-conductive charge storage layer and a gate electrode positioned above said blocking insulation layer. In one illustrative example, the conductive storage layer may be comprised of silicon, germanium, polysilicon, silicon nano-crystals or germanium nano-crystals.

### BRIEF DESCRIPTION OF THE DRAWINGS

The disclosure may be understood by reference to the following description taken in conjunction with the accompanying drawings, in which like reference numerals identify like elements, and in which:

FIG. 1A-1G schematically depict various embodiments of illustrative prior art memory devices and associated energy band diagrams;

FIGS. 2A-2D depict illustrative examples of a novel memory device described herein and associated methods of construction; and

FIGS. 3A-3B depict yet other illustrative examples of a novel memory device described herein, and associated methods of construction.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

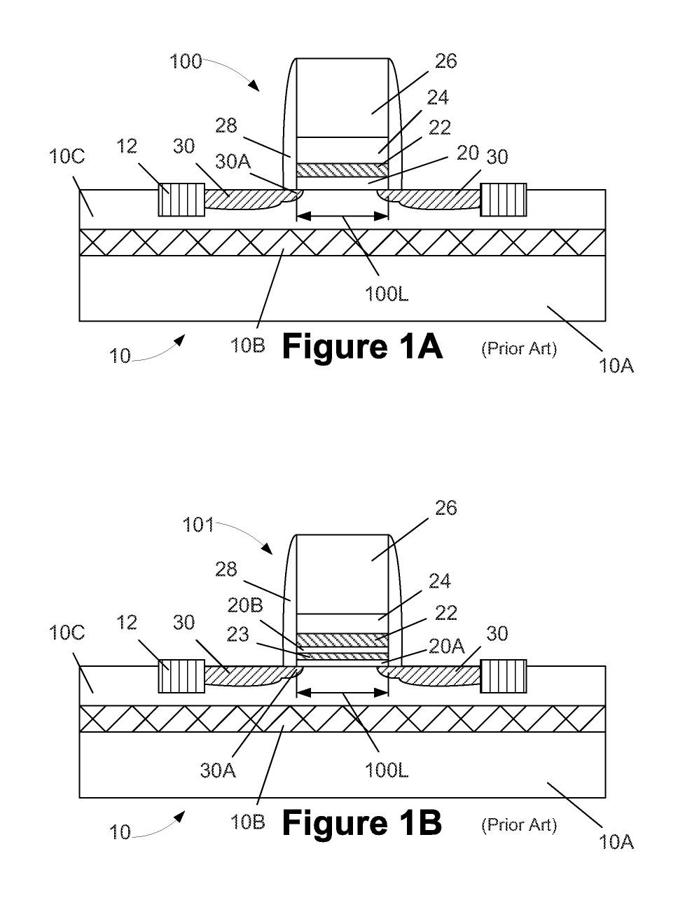

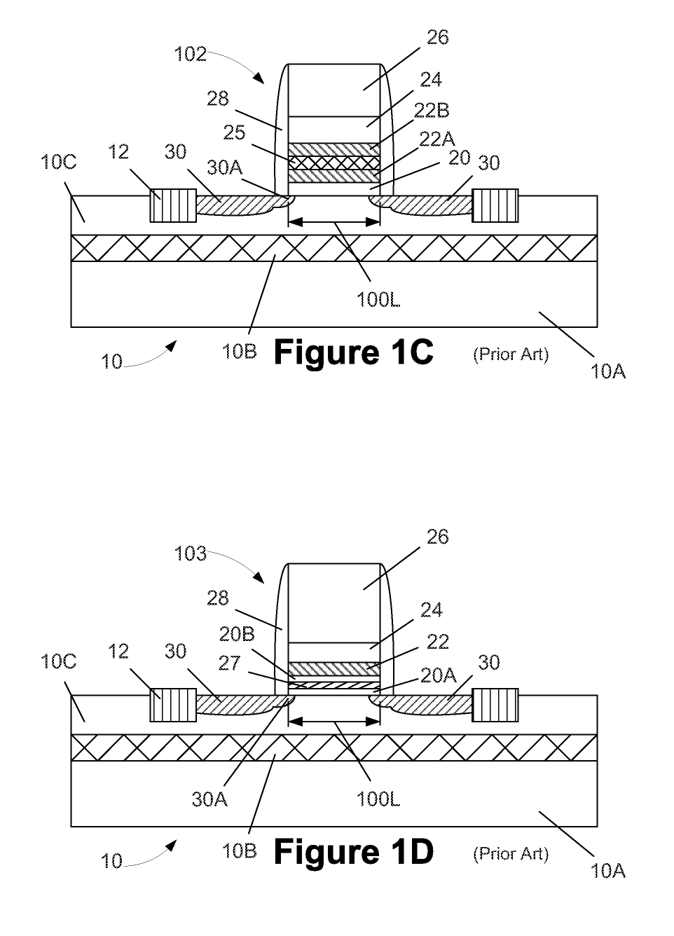

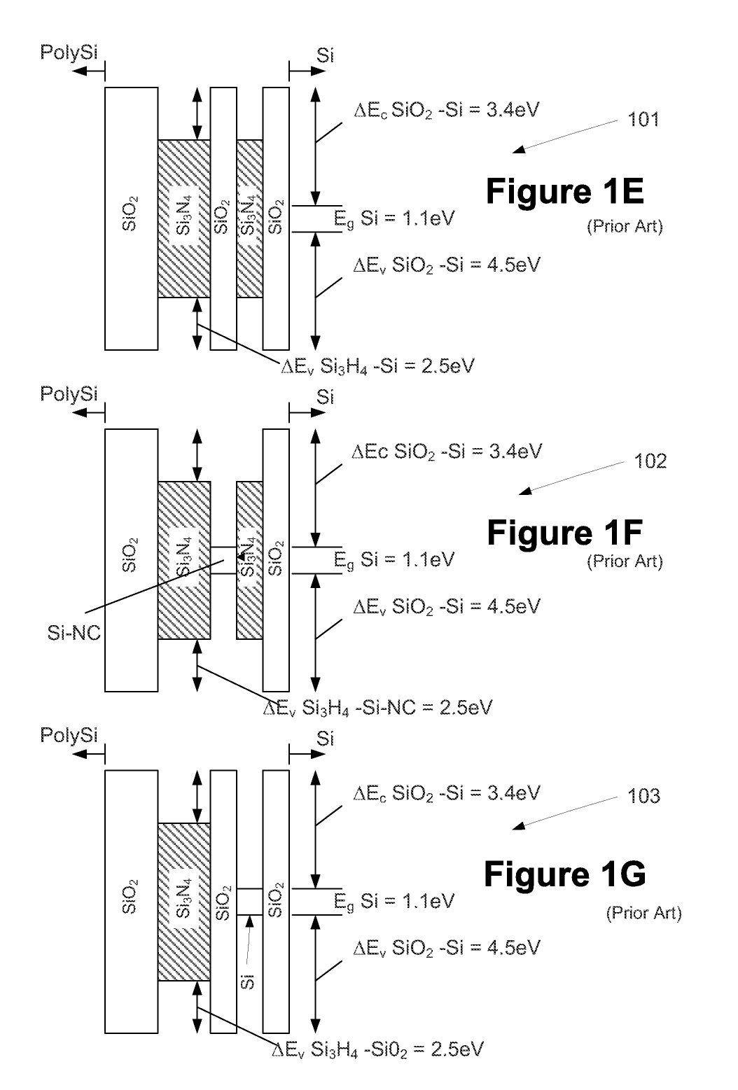

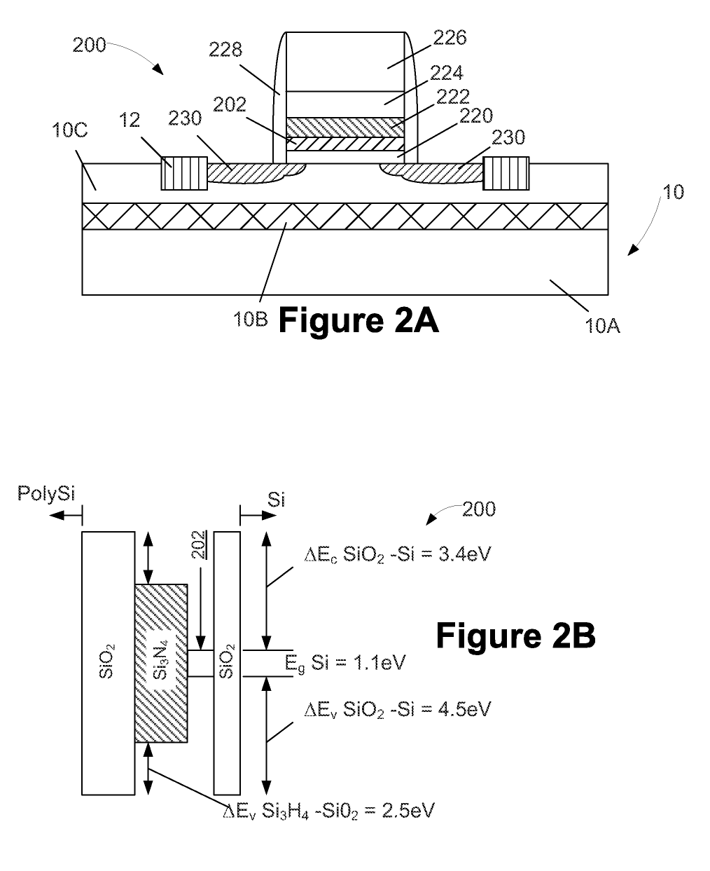

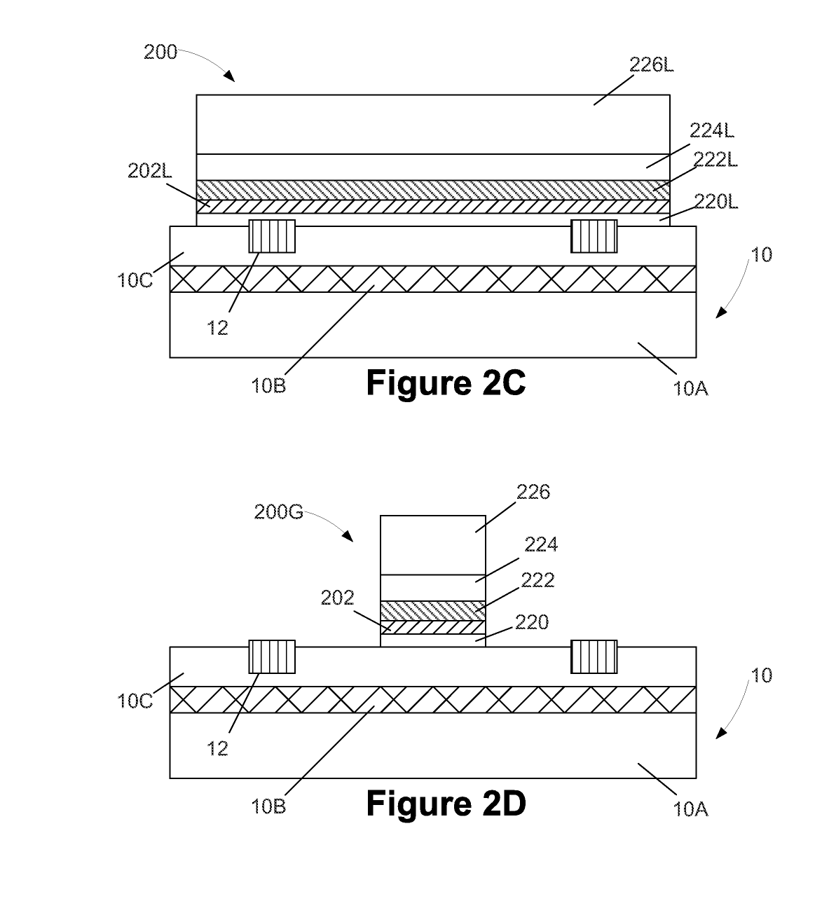

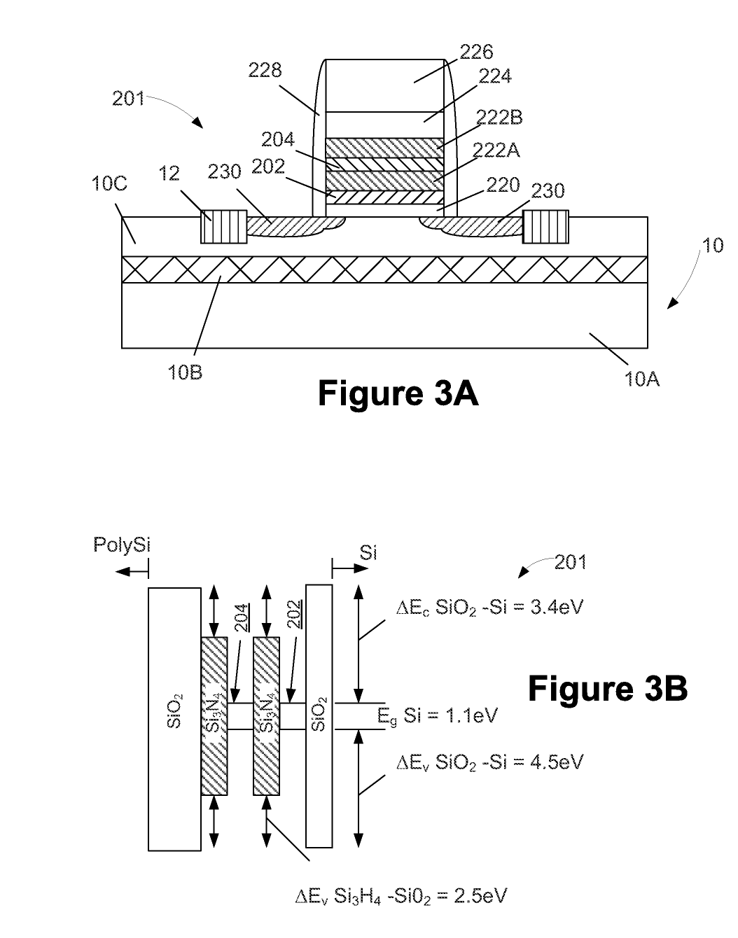

In general, the present disclosure is directed to structures and methods for improving the reliability of memory devices, such as non-volatile memory devices. As will be readily apparent to those skilled in the art upon a complete reading of the present application, the disclosed methods and devices are applicable to both stand-alone or dedicated memory devices as well as embedded memory devices. With reference to FIGS. 2A-3B, various illustrative embodiments of the novel methods and structures disclosed herein will now be described in more detail. Reference may also be made to FIG. 1, if required, wherein the use of the same reference number in the drawings will refer to the same structure as previously described.

FIG. 2A depicts one illustrative example of a novel memory device 200 disclosed herein. FIG. 2B is an energy band diagram for the illustrative memory device 200. In general, the memory device 200 includes a gate insulation layer 220, an electrically conductive storage layer 202, a non-conductive charge storage layer 222, a blocking insulation layer 224, a gate electrode 226, spacers 228, and illustrative source/drain regions 230. The illustrative memory device 200 is formed in and above the active layer 10C of the semiconducting substrate 10. An illustrative isolation structure 12, e.g., a shallow trench isolation structure, that is formed in the substrate 10 is also depicted. In one illustrative embodiment, the semiconducting substrate 10 a silicon-on-insulator (SOI) substrate comprised of bulk silicon 10A, a buried insulation layer 10B (commonly referred to as a “BOX” layer 10B and an active layer 10C, which may also be a silicon material. Of course, the present invention is equally applicable to other configurations of the substrate 10. For example, the substrate 10 may be comprised of semiconducting materials other than silicon and/or it may be in another form, such as a bulk silicon configuration. Thus, the terms substrate or semiconductor substrate should be understood to cover all forms of semiconductor structures.

The gate insulation layer 220 (which is sometimes referred to in the industry as a “tunnel oxide”) may be comprised of a variety of materials, such as silicon dioxide, a combination of silicon dioxide/silicon nitride/silicon dioxide, etc., and it may have a thickness ranging from 5-10 nm. The non-conductive charge storage layer 222, may be comprised of a variety of materials, such as silicon nitride, a silicon rich nitride, a high-k dielectric (k value greater than 10), and it may have a thickness ranging from 5-10 nm. To the extent the non-conductive charge storage layer 22 is comprised of a high-k material, it may be comprised of materials such as the following: tantalum oxide (Ta₂O₅) with a k of approximately 25, strontium titanium oxide (SrTiO₃), having a k of approximately 150, hafnium oxide (HfO₂), HfSiO, zirconium oxide (ZrO₂) and the like. The blocking insulation layer 224, may be comprised of a variety of materials, such as silicon dioxide, a high-k material like those mentioned above, etc., and it may have a thickness ranging from 5-15 nm. The gate electrode 226, may be comprised of a variety of materials of conductive materials, such as polysilicon, amorphous silicon, silicon, silicon-germanium, a metal, etc., and it may have a thickness ranging from 80-150 nm.

The conductive storage layer 202 may be comprised of a variety of materials of conductive materials, such as silicon, germanium, polysilicon, silicon nano-crystals, germanium nano-crystals, etc., and it may have a thickness ranging from 1-3 nm.

In one particularly illustrative example of the memory device 200, the gate insulation layer 220 may be comprised of silicon dioxide, the conductive storage layer 202 may be comprised of silicon nano-crystals, the non-conductive charge storage layer 222 may be comprised of silicon nitride, the blocking insulation layer 224 may be comprised of silicon dioxide, and the gate electrode 226 may be comprised of polysilicon. Additionally, it should be noted that the gate insulation layer 220 and the blocking insulation layer 224 may be made from the same or different insulating materials.

As shown in energy band diagram in FIG. 2B, the presence of the conductive storage layer 202 in the device 200 provides additional deep traps that improve the charge holding capacity of the device 200, especially at high temperatures. By placing the conductive storage layer 202 between the gate insulation layer 220 and the non-conductive charge storage layer 222, there is less impact on the device 200 due to a shift in threshold voltage (Vₜ). For example, as the charges stored in the charge storage layer 222 leak away, the will be trapped by the conductive storage layer 202 which has a larger charge storage capability as compared to the charge storage layer 222. As compared to the prior art memory device 100 shown in FIG. 1A, the new conductive charge storage layer 202 does not significantly alter the energy band diagram because of the negligible voltage drop across the conductive storage layer 202 due to its conductive nature (k of about 11.9 for a layer of silicon), as compared to silicon nitride (k of about 3.6) and silicon dioxide (k of about 3.9). As a result, there is little or no change in the barrier height and hence no significant disruption of programming/erase efficiency of the memory device 200. To the contrary, the memory device 200 may exhibit improved programming/erase efficiencies due to the additional trap centers provided by the conductive storage layer 202. Additionally, with improved data retention, a reduction of the thickness of the gate insulation layer 220 may permit further reductions in cell size. Due to its unique structure, the device 200 has an illustrative energy band diagram that is significantly different than the illustrative energy band diagrams for the prior art devices described in the background section of this application.

FIGS. 2C-2D depict one illustrative process flow that may be employed in manufacturing the illustrative memory device 200 depicted in FIG. 2A. For clarity purposes, only the formation of the gate structure of the device 200 will be depicted in FIGS. 2C-2D. As shown in FIG. 2C, an illustrative stack of materials comprising a gate insulation material layer 220L, a conductive storage material layer 202L, a non-conductive charge storage material layer 222L, a blocking insulation material layer 224L and a gate electrode material layer 226L are formed above the substrate 10. Of course, the depicted layer stack is illustrative in nature as there may be additional layers in the stack depending upon the particular application, or some of the depicted layers may have multiple layers, e.g., the gate electrode material layer 226L may comprise two separate conductive layers. The various material layers 220L, 222L, 224L and 226L may be formed to the desired thickness for each layer using traditional manufacturing techniques such as oxidation, chemical vapor deposition (CVD), physical vapor deposition (PVD), etc. The conductive storage layer 202 may also be formed using traditional techniques. For example, in the case where the conductive storage layer 202 is made of silicon or germanium, a layer of silicon or germanium of the desired thickness may be deposited by performing a CVD or an atomic layer deposition (ALD) process. In the case where the conductive storage layer 202 is made of silicon nano-crystals or germanium nano-crystals, it may be formed by first depositing a layer of silicon or germanium (as appropriate) with a thickness of about 1-3 nm, and thereafter subjecting the device to a heating process at a temperature of about 850-1000 C in an oxidizing ambient for approximately 30 seconds-1 hour. As depicted in FIG. 2C, an illustrative etch mask 40, e.g., photoresist, is also formed above the layer stack using known photolithographic tools and techniques.

Next, as shown in FIG. 2D, multiple etching process are performed to pattern the material layers 220L, 202L, 222L, 224L and 226L to define the basic gate stack 200G. The etching chemistry employed may and likely be different for the various layers depending on the material of each of the layers. In one illustrative embodiment, the material layers are subjected to anisotropic etching processes to define the gate stack 200G, although other etching techniques may be employed. After the etching is complete, the mask 40 is removed. At this point, the gate stack 200G includes the gate insulation material layer 220, the conductive storage layer 202, the non-conductive charge storage layer 22, the blocking insulation layer 224 and the gate electrode 226. Thereafter, sidewall spacers (not shown in FIG. 2D) are formed using traditional techniques, e.g., layer deposition followed by anisotropic etching. Additional processing operations may then be performed to complete the formation of the device, e.g., additional ion implant processes (if needed), forming metallization layers, etc.

FIG. 3A depicts another illustrative example of a novel memory device 201 disclosed herein. FIG. 3B is an energy band diagram for the illustrative memory device 201. In general, the memory device 201 includes a gate insulation layer 220, a first conductive storage layer 202, a first non-conductive charge storage layer 222A, a second conductive storage layer 204, a second non-conductive storage layer 222B, a blocking insulation layer 224, a gate electrode 226, spacers 228, and illustrative source/drain regions 230. The illustrative memory device 201 is formed in and above the active layer 10C of the semiconducting substrate 10. An illustrative isolation structure 12, e.g., a shallow trench isolation structure, that is formed in the substrate 10 is also depicted. In one illustrative embodiment, the semiconducting substrate 10 a silicon-on-insulator (SOI) substrate comprised of bulk silicon 10A, a buried insulation layer 10B (commonly referred to as a “BOX” layer 10B and an active layer 10C, which may also be a silicon material. Of course, the present invention is equally applicable to other configurations of the substrate 10. For example, the substrate 10 may be comprised of semiconducting materials other than silicon and/or it may be in another form, such as a bulk silicon configuration. Thus, the terms substrate or semiconductor substrate should be understood to cover all forms of semiconductor structures.

The gate insulation layer 220 (which is sometimes referred to in the industry as a “tunnel oxide”), the blocking insulating layer 224 and the gate electrode 226 may be as previously described in connection with FIGS. 2A-2D above. The first and second non-conductive charge storage layers 222A, 222B may be comprised of a variety of materials, such as silicon nitride, a silicon rich nitride, a high-k dielectric (k value greater than 10), etc., and each of the layers 222A, 222B may have a thickness ranging from 2-5 nm. The first and second non-conductive charge storage layers 222A, 222B need not be made of the same material and they need not be the same thickness. Moreover, the material and thickness of each of the first and second non-conductive charge storage layers 222A, 222B may vary depending upon the particular application. To the extent either or both of the first and second non-conductive charge storage layers 222A, 222B is comprised of a high-k material, they may be comprised of materials such as the following: tantalum oxide (Ta₂O₅) with a k of approximately 25, strontium titanium oxide (SrTiO₃), having a k of approximately 150, hafnium oxide (HfO₂), HfSiO, zirconium oxide (ZrO₂) and the like.

The second conductive storage layer 204 may have the same construction as previously describe for the conductive storage layer 202 discussed in FIGS. 2A-2D above. The first and second conductive storage layers 202, 204 need not be made of the same material and they need not be the same thickness in any given memory device 201. Moreover, the material and thickness of each of the first and second conductive storage layers 202, 204 may vary depending upon the particular application.

In one particularly illustrative example of the memory device 201, the gate insulation layer 220 may be comprised of silicon dioxide, the first conductive charge storage layer 202 may be comprised of silicon, the first non-conductive charge storage layer 222A may be comprised of silicon nitride, the second conductive charge storage layer 204 may be comprised of germanium nano-crystals, the second non-conductive charge storage layer 222B may be comprised of silicon nitride, the blocking insulation layer 224 may be comprised of silicon dioxide, and the gate electrode 226 may be comprised of polysilicon.

As shown in energy band diagram in FIG. 3B, the presence of the additional conductive storage layer 204 in the device 201, in combination with the first conductive charge storage layer 202, provides additional deep traps that improve the charge holding capacity of the device 201, especially at high temperatures. The additional conductive charge storage layers 202, 204 does not significantly alter the energy band diagram, as compared to the prior art memory device 100 shown in FIG. 1A, because of the negligible voltage drop across the conductive storage layers 202, 204 due to their conductive nature (k of about 11.9 for a layer of silicon), as compared to silicon nitride (k of about 3.6) and silicon dioxide (k of about 3.9). As a result there is little or no change in the barrier height and hence no significant disruption of programming/erase efficiency of the memory device 201. To the contrary, the device 201 may exhibit improved programming/erase efficiencies due to the additional trap centers provided by the conductive layer 204. Additionally, with improved data retention, a reduction of the thickness of the gate insulation layer 220 may permit further reductions in cell size. Due to its unique structure, the device 201 has an illustrative energy band diagram that is significantly different than the illustrative energy band diagrams for the prior art devices described in the background section of this application.

The memory device 201 may be formed in a manner similar to the memory device 200 as described in FIGS. 2C-2D. That is, a stack of materials layers that will be etched to form the gate insulation layer 220, the first conductive storage layer 202, the first non-conductive charge storage layer 222A, the second conductive storage layer 204, the second non-conductive storage layer 222B, the blocking insulation layer 224 and the gate electrode 226 may be formed above the substrate 10. Of course, the aforementioned layer stack is illustrative in nature as there may be additional layers in the stack depending upon the particular application, or some of the depicted layers may have multiple layers, e.g., the gate electrode 226 may comprise two separate conductive layers. After these layers are etched to define a gate stack, additional processing operations may then be performed to complete the formation of the device, e.g., formation of sidewall spacers, performing additional ion implant processes (if needed), forming metallization layers, etc.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modi-fied and all such variations are considered within the scope and spirit of the invention. Accordingly, the protection sought herein is as set forth in the claims below.

What is claimed:

1. A memory device, comprising:
a gate insulation layer;
a first conductive storage layer positioned above the gate insulation layer;
a first non-conductive charge storage layer positioned above the first conductive storage layer;
a blocking insulation layer positioned above said first non-conductive charge storage layer; and
a gate electrode positioned above said blocking insulation layer.

2. The device of claim 1, wherein said first conductive storage layer is comprised of at least one of silicon, germanium, polysilicon, silicon nano-crystals and germanium nano-crystals.

3. The device of claim 1, wherein said first non-conductive charge storage layer is comprised of at least one of silicon nitride and silicon rich nitride.

4. The device of claim 1, wherein said first conductive storage layer contacts said gate insulation layer, said first non-conductive charge storage layer contacts said first conductive storage layer, said blocking insulation layer contacts said first non-conductive charge storage layer and said gate electrode contacts said blocking insulation layer.

5. The device of claim 1, further comprising:
a second conductive storage layer positioned above said first non-conductive charge storage layer; and
a second non-conductive charge storage layer positioned above said second conductive storage layer and below said blocking insulation layer.

6. The device of claim 5, wherein said first and second conductive storage layers are comprised of the same material.

7. The device of claim 5, wherein said first and second conductive storage layers are comprised of different materials.

8. The device of claim 5, wherein said first and second non-conductive charge storage layers are comprised of the same material.

9. The device of claim 5, wherein said first and second non-conductive charge storage layers are comprised of different materials.

10. The device of claim 5, wherein said second conductive storage layer is comprised of at least one of silicon, germanium, polysilicon, silicon nano-crystals and germanium nano-crystals.

11. The device of claim 5, wherein said second non-conductive charge storage layer is comprised of at least one of silicon nitride and silicon rich nitride.

12. The device of claim 1, wherein said charge storage layer is comprised of silicon nitride and said gate electrode is comprised polysilicon.

13. The device of claim 1, wherein said charge storage layer is comprised of a conductive material.

14. The device of claim 1, wherein said charge storage layer and said gate electrode are made of the same material.

15. A device, comprising:
a gate insulation layer comprised of silicon dioxide;
a first conductive storage layer positioned on the gate insulation layer;
a first non-conductive charge storage layer comprised of silicon nitride positioned on the first conductive storage layer;
a blocking insulation layer positioned above the first non-conductive charge storage layer; and
a gate electrode comprised of polysilicon positioned on said blocking insulation layer.

16. The device of claim 15, further comprising:
a second conductive storage layer positioned above said first non-conductive charge storage layer; and
a second non-conductive charge storage layer positioned above said second conductive storage layer and below said blocking insulation layer.

17. The device of claim 16, wherein said second conductive storage layer contacts said first non-conductive charge storage layer and said second non-conductive charge storage layer contacts said second conductive storage layer.
